(19) United States
(12) Patent Application Publication
(10) Pub. No.: US 2026/0233497 A1
(43) Pub. Date: Aug. 13, 2026

(54) RESIN FILM, METAL-CLAD LAMINATE, PRINTED WIRING BOARD, AND METHOD FOR PRODUCING RESIN FILM

(71) Applicants: TOYOBO CO., LTD., Osaka-shi, Osaka (JP); THE UNIVERSITY OF OSAKA, Suita-shi, Osaka (JP)

(72) Inventors: Toshiyuki TSUCHIYA, Osaka (JP); Mitsumasa ONO, Osaka (JP); Yuji OHKUBO, Suita (JP); Kazuya YAMAMURA, Suita (JP); Daiki KAJIMARU, Suita (JP)

(73) Assignees: TOYOBO CO., LTD., Osaka-shi, Osaka (JP); THE UNIVERSITY OF OSAKA, Suita-shi, Osaka (JP)

(21) Appl. No.: 19/154,882

(22) PCT Filed: May 13, 2024
(86) PCT No.: PCT/JP2024/017606

§ 371 Date: Aug. 8, 2025

(30) Foreign Application Priority Data
Jun. 19, 2023 (JP) 2023-099864

(51) Int. Cl. B32B 27/08; B32B 15/085; B32B 15/20; B32B 27/28; B32B 27/32; B32B 37/06; B32B 37/10; H05K 1/03; H05K 1/09; H05K 3/00

(52) U.S. Cl. CPC B32B 27/08; B32B 15/085; B32B 15/20; B32B 27/281; B32B 27/322; B32B 37/06; B32B 37/10; H05K 1/036; H05K 1/09; H05K 3/0064; B32B 2250/04; B32B 2307/7376; B32B 2309/02; B32B 2457/08; H05K 2201/015; H05K 2201/0154; H05K 2201/0355; H05K 2203/065; H05K 2203/095

(57) ABSTRACT

An object of the present invention is to provide a resin film and a metal-clad laminate that can be used to produce a printed wiring board having excellent dimensional stability and reduced transmission loss. Another object of the present invention is to provide a method for producing a resin film that can be used to produce a printed wiring board having excellent dimensional stability and reduced transmission loss. The present invention relates to a resin film 7 including a polyimide film 70 and a PTFE film 71 that is directly laminated on the polyimide film 70. In the resin film 7, the peel strength when the PTFE film 71 is peeled off is 0.5 N/mm or more.

### TECHNICAL FIELD

The present invention relates to a resin film, a metal-clad laminate, a printed wiring board, and a method for producing a resin film.

### BACKGROUND ART

In order to achieve large-volume communication and high-speed communication of information, it is required to reduce transmission loss in printed wiring boards. The transmission loss consists of conductor loss and dielectric loss. The dielectric loss can be reduced by reducing the relative permittivity and dielectric loss tangent of the dielectric material. Meanwhile, dielectric loss increases as the signal frequency increases. As the use of high frequency bands progresses, the importance of reducing the relative permittivity and dielectric loss tangent of resin films used in the production of printed wiring boards is increasing.

In order to reduce the relative permittivity and the dielectric loss tangent, polytetrafluoroethylene (namely, PTFE) is sometimes used as one of the materials for printed wiring boards (see, for example, Patent Documents 1 and 2). PTFE exhibits the lowest permittivity and the lowest dielectric loss tangent among fluororesins. This is because PTFE has a repeating structure of —(CF₂—CF₂)—.

Meanwhile, polyimide is also sometimes used as one of the materials for printed wiring boards (see, for example, Patent Document 3). This is because polyimide exhibits excellent heat resistance, insulating properties, dimensional stability, and the like. Polyimide is particularly suitably used as one of the materials for insulating substrates of flexible printed wiring boards.

In the technology of Patent Document 3 in which polyimide is used, in order to reduce the relative permittivity and dielectric loss tangent, both surfaces of the polyimide layer are provided with a fluororesin other than PTFE, specifically, fluororesins such as tetrafluoroethylene-perfluoroalkyl vinyl ether copolymer (namely, PFA) and tetrafluoroethylene-hexafluoropropylene copolymer (namely, FEP).

### PRIOR ART DOCUMENTS

### Patent Documents

Patent Document 1: JP-A-2002-307611
Patent Document 2: JP-A-2005-163006
Patent Document 3: JP-B-5625906
Patent Document 4: JP-A-2012-233038

### SUMMARY OF THE INVENTION

### Problems to be Solved by the Invention

The printed wiring board produced using the technology of Patent Document 3 includes a resin film including a first fluororesin layer, a polyimide layer, and a second fluororesin layer, and therefore has excellent dimensional stability and reduced transmission loss, but there is still room for improvement. There is still room for improvement particularly in terms of reduction in transmission loss.

An object of the present invention is to provide a resin film and a metal-clad laminate that can be used to produce a printed wiring board having excellent dimensional stability and reduced transmission loss. Another object of the present invention is to provide a method for producing a resin film that can be used to produce a printed wiring board having excellent dimensional stability and reduced transmission loss.

### Means for Solving the Problems

In order to solve this problem, the present invention has the following configuration of [1].

[1]

A resin film including:
a polyimide film; and
a first polytetrafluoroethylene film that is directly laminated on the polyimide film, in which
a peel strength when the first polytetrafluoroethylene film is peeled off is 0.5 N/mm or more.

According to [1], since the resin film includes a polyimide film, the resin film can be excellent in dimensional stability.

Moreover, since the resin film includes the first polytetrafluoroethylene film (namely, the first PTFE film), the relative permittivity and dielectric loss tangent of the resin film can be reduced. This is because PTFE exhibits the lowest relative permittivity and the lowest dielectric loss tangent among fluororesins such as tetrafluoroethylene-perfluoroalkyl vinyl ether copolymer (namely, PFA) and tetrafluoroethylene-hexafluoropropylene copolymer (namely, FEP).

In addition, since the first PTFE film is directly laminated on the polyimide film, the relative permittivity and dielectric loss tangent of the resin film can be further reduced. This will be explained. If PTFE and polyimide are to be bonded together with an adhesive, it is considered that the relative permittivity and dielectric loss tangent are increased by the adhesive. In contrast, according to [1], the first PTFE film is directly laminated on the polyimide film, that is, the first PTFE film is bonded to the polyimide film without an adhesive. Therefore, it is possible to avoid an increase in the relative permittivity and dielectric loss tangent that may be caused by the adhesive. Hence, the relative permittivity and dielectric loss tangent of the resin film can be further reduced. Furthermore, since the peel strength is 0.5 N/mm or more, undesired peeling off of the first PTFE film can be suppressed. Therefore, it is possible to suppress peeling off of the first PTFE film from the polyimide film that may occur by the impact that the resin film may receive and a change in temperature, a change in humidity, and the like.

Hence, according to the resin film according to [1], it is possible to produce a printed wiring board having excellent dimensional stability and reduced transmission loss.

In the present invention, the following configurations of [2] to [7] are preferable.

[2]

The resin film according to [1], further including a second polytetrafluoroethylene film that is directly laminated on the polyimide film, in which
the first polytetrafluoroethylene film, the polyimide film, and the second polytetrafluoroethylene film are arranged in this order in a thickness direction of the resin film, and
a peel strength when the second polytetrafluoroethylene film is peeled off is 0.5 N/mm or more.
   [3]

The resin film according to [2], which has a relative permittivity of 3.0 or less at 28 GHz.

[4]

The resin film according to [2] or [3], which has a dielectric loss tangent of 0.004 or less at 28 GHz.

[5]

The resin film according to any one of [2] to [4], in which a total thickness of the first polytetrafluoroethylene film and the second polytetrafluoroethylene film is 60% or more and 90% or less in 100% of a total thickness of the first polytetrafluoroethylene film, the polyimide film, and the second polytetrafluoroethylene film.

[6]

The resin film according to any one of [1] to [5], in which the polyimide film contains a polyimide containing a polyimide benzoxazole component.

[7]

The resin film according to any one of [1] to [6], which is used to produce at least one of a metal-clad laminate or a printed wiring board.

[8]

The resin film according to any one of [1] to [7], which has a coefficient of linear thermal expansion of 30 ppm/° C. or less at 50° C. to 200° C.

The present invention also relates to the following configuration of [9].

[9]

A metal-clad laminate including:
the resin film according to any one of [1] to [8]; and
a metal foil that is provided with the first polytetrafluoroethylene film of the resin film.

The present invention also relates to the following configuration of [10].

[10]

A printed wiring board that is produced using the resin film according to any one of [1] to [8].

The present invention also relates to the following configuration of [11].

[11]

A method for producing the resin film according to any one of [1] to [8], the method including:
a step of performing a plasma treatment on a surface of the first polytetrafluoroethylene film at an oxygen concentration of less than 0.5% by volume; and
a step of performing thermocompression bonding on the plasma-treated first polytetrafluoroethylene film and the polyimide film in a state where the plasma-treated surface of the first polytetrafluoroethylene film faces the polyimide film, in which
a temperature of the surface of the first polytetrafluoroethylene film is 180° C. or more in the step of performing the plasma treatment.

According to [11], since a plasma treatment is performed on the surface of the first PTFE film, the carbon-fluorine bond in the PTFE molecule can be broken.

Moreover, since the plasma treatment is performed at a surface temperature of the first PTFE film of 180° C. or more, it is possible to improve the mobility of PTFE molecules on the surface of the first PTFE film, and therefore, a PTFE molecule having the carbon atom of a carbon-fluorine bond broken by irradiation with plasma can be effectively bonded to another PTFE molecule having a carbon atom similarly broken. In other words, it is possible to actively promote the formation of carbon-carbon bonds between PTFE molecules. In short, it is possible to actively promote the crosslinking reaction. Hence, the surface hardness of the first PTFE film can be improved (this may be rephrased as that the weakened layer on the surface of the first PTFE film can be repaired or removed). As a result, the adhesive properties of the first PTFE film to the polyimide film, that is, the peel strength, can be improved.

In addition, since the plasma treatment is performed at an oxygen concentration of less than 0.5% by volume, it is possible to avoid inhibition of carbon-carbon bond formation by oxygen (hereinafter sometimes referred to as “oxygen inhibition”), and therefore, the surface hardness of the first PTFE film can be further improved. Hence, the adhesive properties of the first PTFE film to the polyimide film, that is, the peel strength, can be further improved.

### Effect of the Invention

According to the present invention, it is possible to provide a resin film and a metal-clad laminate that can be used to produce a printed wiring board having excellent dimensional stability and reduced transmission loss. According to the present invention, it is possible to provide a method for producing a resin film that can be used to produce a printed wiring board having excellent dimensional stability and reduced transmission loss.

### BRIEF DESCRIPTION OF THE DRAWINGS

FIG. 1 is a schematic cross-sectional view of a resin film in the present embodiment.

FIG. 2A is a conceptual diagram of an atmospheric pressure plasma treatment apparatus that can be used in the present embodiment.

FIG. 2B is a conceptual diagram illustrating a partly enlarged view of the periphery of an electrode constituting an atmospheric pressure plasma treatment apparatus that can be used in the present embodiment.

FIG. 3 is a schematic cross-sectional view of a metal-clad laminate in the present embodiment.

### MODE FOR CARRYING OUT THE INVENTION

Hereinafter, embodiments of the present invention will be described in detail.

### <1. Resin Film>

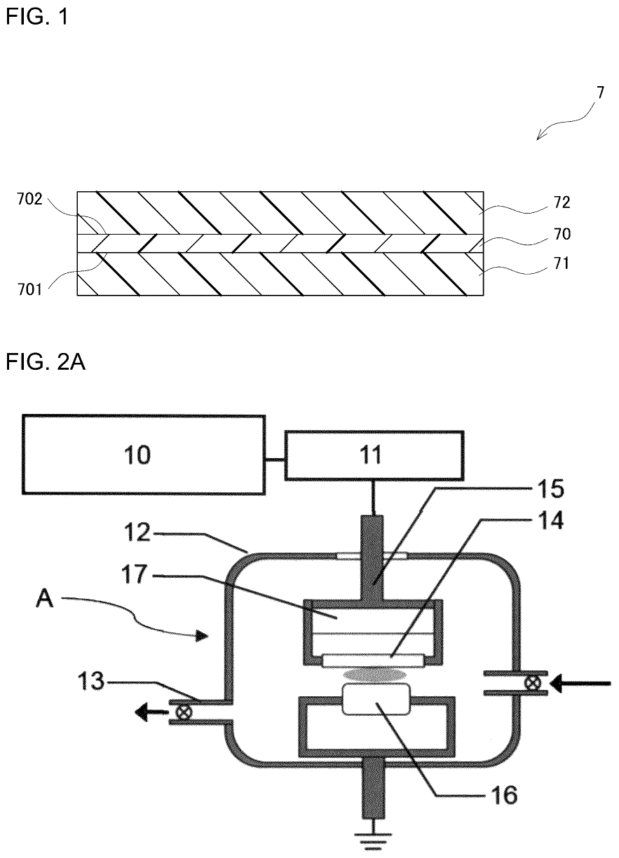

As illustrated in FIG. 1, a resin film 7 of the present embodiment includes a polyimide film 70, a polytetrafluoroethylene film (namely, PTFE film) 71, and a polytetrafluoroethylene film (namely, PTFE film) 72. In the resin film 7, the PTFE film 71, the polyimide film 70, and the PTFE film 72 are arranged in this order in the thickness direction of the resin film 7. In other words, the PTFE film 71, the polyimide film 70, and the PTFE film 72 are laminated in this order. Since these are arranged in this order, the resin film 7 can be excellent in low moisture absorption properties.

### <1.1. Polyimide Film>

The resin film 7 includes the polyimide film 70. The polyimide film 70 includes a surface 701 and a surface 702. The surface 701 faces the PTFE film 71. Meanwhile, the surface 702 faces the PTFE film 72. The resin film 7 includes the polyimide film 70, and therefore can be excellent in dimensional stability.

Both surfaces of the polyimide film 70, that is, the surface 701 and the surface 702, are preferably subjected to surface modification. As the surface 701 and the surface 702 are subjected to surface modification, it is possible to increase the peel strength when the PTFE film 71 and the PTFE film 72 are peeled off from the polyimide film 70, and therefore, undesired peeling off of the PTFE film 71 and the PTFE film 72 can be further suppressed.

The thickness of the polyimide film 70 is preferably 1 μm or more, more preferably 5 μm or more. Meanwhile, the thickness of the polyimide film 70 is preferably 60 μm or less, more preferably 40 μm or less, still more preferably 38 μm or less.

The storage modulus of the polyimide film 70 at 25° C. is preferably 6.0 GPa or more, more preferably 7.0 GPa or more, still more preferably 8.0 GPa or more. The storage modulus of the polyimide film 70 at 25° C. can be measured using the following apparatus and conditions.
Apparatus name: Rheogel-E4000 manufactured by UBM
Jig: Tension jig
Length of sample: 14 mm
Width of sample: 5 mm
Frequency: 10 Hz
Start temperature in temperature increase: 0° C.
Rate of temperature increase: 5° C./min
Atmosphere: Nitrogen

The polyimide film 70 includes a polyimide. The polyimide film 70 can be formed by, for example, a method including casting a polyamic acid solution obtained by reacting an aromatic tetracarboxylic acid (hereinafter, anhydrides, acids, and amide-bonded derivatives of aromatic tetracarboxylic acids are collectively referred to as “aromatic tetracarboxylic acids”) with an aromatic diamine (hereinafter, amine and amide-bonded derivatives of aromatic diamines are collectively referred to as “aromatic diamines”), and performing drying and heat treatment (imidization).

The polyimide preferably contains a polyimidebenzoxazole component. Here, the term “polyimide containing a polyimide benzoxazole component” means a polyimide containing a benzoxazole structure. An example of the polyimide containing a polyimide benzoxazole component is a polyimide obtained by polycondensation of an aromatic diamine having a benzoxazole structure and an aromatic tetracarboxylic anhydride.

As for the polyimide, preferred combinations of aromatic tetracarboxylic acids with aromatic diamines include the following examples.

A. A combination of an aromatic tetracarboxylic acid having a pyromellitic acid residue with an aromatic diamine having a benzoxazole structure.

B. A combination of an aromatic diamine having a phenylenediamine skeleton with an aromatic tetracarboxylic acid having a biphenyltetracarboxylic acid skeleton.

C. A combination of an aromatic diamine having a diphenyl ether skeleton with an aromatic tetracarboxylic acid having a pyromellitic acid residue.

Among these, the combination of A is preferable.

Examples of the aromatic diamine having a benzoxazole structure include the following. These diamines account for preferably 70 mol % or more, more preferably 80 mol % or more of the total diamines.

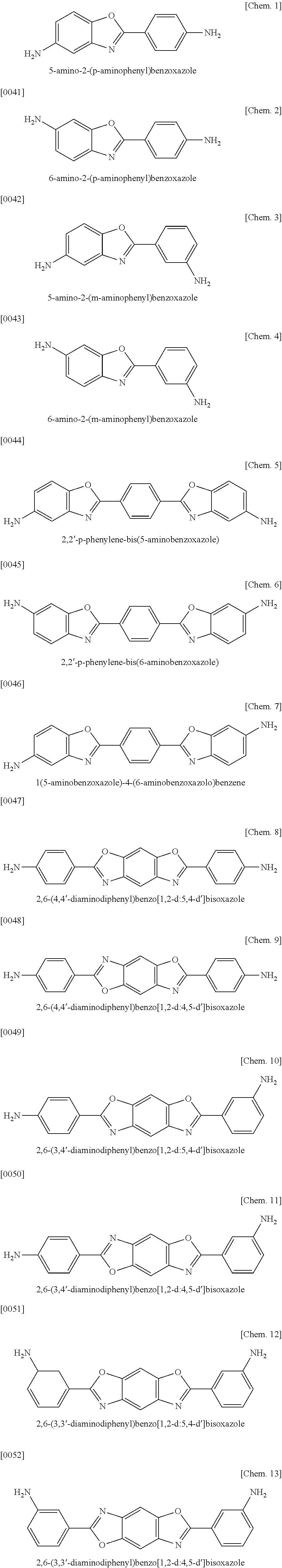

Among these, from the viewpoint of ease of synthesis, each isomer of amino (aminophenyl)benzoxazole is preferable, and 5-amino-2-(p-aminophenyl)benzoxazole is more preferable. Here, “each isomer” is each isomer determined according to the coordination positions of the two amino groups of amino (aminophenyl)benzoxazole (example: each compound represented by “Chem. 1” to “Chem. 4”). These diamines may be used singly or in combination of two or more kinds thereof.

Furthermore, one or two or more of diamines exemplified below may be used in combination. Examples of such diamines include: 4,4′-bis(3-aminophenoxy) biphenyl, bis[4-(3-aminophenoxy)phenyl]ketone, bis[4-(3-aminophenoxy)phenyl]sulfide, bis[4-(3-aminophenoxy)phenyl]sulfone, 2,2-bis[4-(3-aminophenoxy)phenyl]propane, 2,2-bis[4-(3-aminophenoxy)phenyl]-1,1,1,3,3,3-hexafluoropropane, m-phenylenediamine, o-phenylenediamine, p-phenylenediamine, m-aminobenzylamine, p-aminobenzylamine, 3,3′-diaminodiphenyl ether, 3,4′-diaminodiphenyl ether, 4,4′-diaminodiphenyl ether, 3,3′-diaminodiphenyl sulfide, 3,3′-diaminodiphenyl sulfoxide, 3,4′-diaminodiphenyl sulfoxide, 4,4′-diaminodiphenyl sulfoxide, 3,3′-diaminodiphenyl sulfone, 3,4′-diaminodiphenyl sulfone, 4,4′-diaminodiphenyl sulfone, 3,3′-diaminobenzophenone, 3,4′-diaminobenzophenone, 4,4′-diaminobenzophenone, 3,3′-diaminodiphenylmethane, 3,4′-diaminodiphenylmethane, 4,4′-diaminodiphenylmethane, bis[4-(4-aminophenoxy)phenyl]methane, 1,1-bis[4-(4-aminophenoxy)phenyl]ethane, 1,2-bis[4-(4-aminophenoxy)phenyl]ethane, 1,1-bis[4-(4-aminophenoxy)phenyl]propane, 1,2-bis[4-(4-aminophenoxy)phenyl]propane, 1,3-bis[4-(4-aminophenoxy)phenyl]propane, 2,2-bis[4-(4-aminophenoxy)phenyl]propane, 1,1-bis[4-(4-aminophenoxy)phenyl]butane, 1,3-bis[4-(4-aminophenoxy)phenyl]butane, 1,4-bis[4-(4-aminophenoxy)phenyl]butane, 2,2-bis[4-(4-aminophenoxy)phenyl]butane, 2,3-bis[4-(4-aminophenoxy)phenyl]butane, 2-[4-(4-aminophenoxy)phenyl]-2-[4-(4-aminophenoxy)-3-methylphenyl]propane, 2,2-bis[4-(4-aminophenoxy)-3-methylphenyl]propane, 2-[4-(4-aminophenoxy)phenyl]-2-[4-(4-aminophenoxy)-3,5-dimethylphenyl]propane, 2,2-bis[4-(4-aminophenoxy)-3,5-dimethylphenyl]propane, 2,2-bis[4-(4-aminophenoxy)phenyl]-1,1,1,3,3,3-hexafluoropropane, 1,4-bis(3-aminophenoxy)benzene, 1,3-bis(3-aminophenoxy)benzene, 1,4-bis(4-aminophenoxy)benzene, 4,4′-bis(4-aminophenoxy) biphenyl, bis[4-(4-aminophenoxy)phenyl]ketone, bis[4-(4-aminophenoxy)phenyl]sulfide, bis[4-(4-aminophenoxy)phenyl]sulfoxide, bis[4-(4-aminophenoxy)phenyl]sulfone, bis[4-(3-aminophenoxy)phenyl]ether, bis[4-(4-aminophenoxy)phenyl]ether, 1,3-bis[4-(4-aminophenoxy)benzoyl]benzene, 1,3-bis[4-(3-aminophenoxy)benzoyl]benzene, 1,4-bis[4-(3-aminophenoxy)benzoyl]benzene, 4,4′-bis[(3-aminophenoxy)benzoyl]benzene, 1,1-bis[4-(3-aminophenoxy)phenyl]propane, 1,3-bis[4-(3-aminophenoxy)phenyl]propane, 3,4′-diaminodiphenyl sulfide, 2,2-bis[3-(3-aminophenoxy)phenyl]-1,1,1,3,3,3-hexafluoropropane, bis[4-(3-aminophenoxy)phenyl]methane, 1,1-bis[4-(3-aminophenoxy)phenyl]ethane, 1,2-bis[4-(3-aminophenoxy)phenyl]ethane, bis[4-(3-aminophenoxy)phenyl]sulfoxide, 4,4′-bis[3-(4-aminophenoxy)benzoyl]diphenyl ether, 4,4′-bis[3-(3-aminophenoxy)benzoyl]diphenyl ether, 4,4′-bis[4-(4-amino-α,α-dimethylbenzyl) phenoxy]benzophenone, 4,4′-bis[4-(4-amino-α,α-dimethylbenzyl) phenoxy]diphenyl sulfone, bis[4-{4-(4-aminophenoxy) phenoxy}phenyl]sulfone, 1,4-bis[4-(4-aminophenoxy) phenoxy-α,α-dimethylbenzyl]benzene, 1,3-bis[4-(4-aminophenoxy) phenoxy-α,α-dimethylbenzyl]benzene, 1,3-bis[4-(4-amino-6-trifluoromethylphenoxy)-α,α-dimethylbenzyl]benzene, 1,3-bis[4-(4-amino-6-fluorophenoxy)-α,α-dimethylbenzyl]benzene, 1,3-bis[4-(4-amino-6-methylphenoxy)-α,α-dimethylbenzyl]benzene, 1,3-bis[4-(4-amino-6-cyanophenoxy)-α,α-dimethylbenzyl]benzene, 3,3′-diamino-4,4′-diphenoxybenzophenone, 4,4′-diamino-5,5′-diphenoxybenzophenone, 3,4′-diamino-4,5′-diphenoxybenzophenone, 3,3′-diamino-4-phenoxybenzophenone, 4,4′-diamino-5-phenoxybenzophenone, 3,4′-diamino-4-phenoxybenzophenone, 3,4′-diamino-5′-phenoxybenzophenone, 3,3′-diamino-4,4′-diphenylphenoxybenzophenone, 4,4′-diamino-5,5′-diphenylphenoxybenzophenone, 3,4′-diamino-4,5′-diphenylphenoxybenzophenone, 3,3′-diamino-4-biphenoxybenzophenone, 4,4′-diamino-5-biphenoxybenzophenone, 3,4′-diamino-4-biphenoxybenzophenone, 3,4′-diamino-5′-biphenoxybenzophenone, 1,3-bis(3-amino-4-phenoxybenzoyl)benzene, 1,4-bis(3-amino-4-phenoxybenzoyl)benzene, 1,3-bis(4-amino-5-phenoxybenzoyl)benzene, 1,4-bis(4-amino-5-phenoxybenzoyl)benzene, 1,3-bis(3-amino-4-biphenoxybenzoyl)benzene, 1,4-bis(3-amino-4-biphenoxybenzoyl)benzene, 1,3-bis(4-amino-5-biphenoxybenzoyl)benzene, 1,4-bis(4-amino-5-biphenoxybenzoyl)benzene, 2,6-bis[4-(4-amino-α,α-dimethylbenzyl) phenoxy]benzonitrile, and aromatic diamines obtained by substituting some or all of hydrogen atoms on an aromatic ring of the aromatic diamines with halogen atoms; alkyl groups or alkoxyl groups having 1 to 3 carbon atoms; cyano groups; or halogenated alkyl groups or alkoxy groups having 1 to 3 carbon atoms obtained by substituting some or all of hydrogen atoms of alkyl groups or alkoxyl groups with halogen atoms. These diamines account for preferably 30 mol % or less, more preferably 20 mol % or less of the total diamines.

Examples of the aromatic tetracarboxylic anhydride include the following. These acid anhydrides account for preferably 70 mol % or more, more preferably 80 mol % or more of the total acid anhydrides.

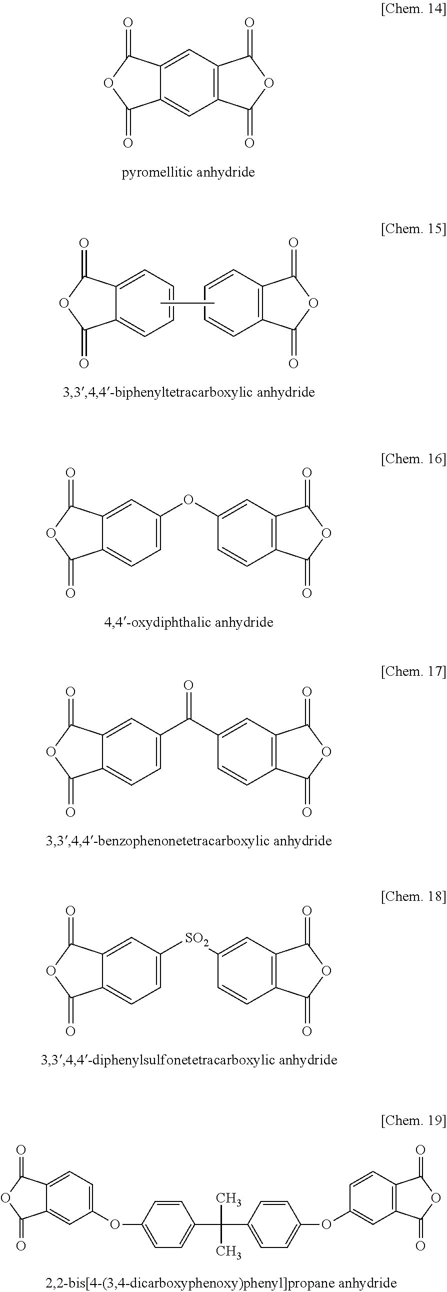

The aromatic tetracarboxylic anhydrides may be used singly or in combination of two or more kinds thereof.

Furthermore, one or two or more of non-aromatic tetracarboxylic dianhydrides exemplified below may be used in combination. Examples of such tetracarboxylic anhydrides include: butane-1,2,3,4-tetracarboxylic dianhydride, pentane-1,2,4,5-tetracarboxylic dianhydride, cyclobutanetetracarboxylic dianhydride, cyclopentane-1,2,3,4-tetracarboxylic dianhydride, cyclohexane-1,2,4,5-tetracarboxylic dianhydride, cyclohex-1-ene-2,3,5,6-tetracarboxylic dianhydride, 3-ethylcyclohex-1-ene-3-(1,2),5,6-tetracarboxylic dianhydride, 1-methyl-3-ethylcyclohexane-3-(1,2),5,6-tetracarboxylic dianhydride, 1-methyl-3-ethylcyclohex-1-ene-3-(1,2),5,6-tetracarboxylic dianhydride, 1-ethylcyclohexane-1-(1,2),3,4-tetracarboxylic dianhydride, 1-propylcyclohexane-1-(2,3),3,4-tetracarboxylic dianhydride, 1,3-dipropylcyclohexane-1-(2,3),3-(2,3)-tetracarboxylic dianhydride, dicyclohexyl-3,4,3′,4′-tetracarboxylic dianhydride, bicyclo[2.2.1]heptane-2,3,5,6-tetracarboxylic dianhydride, 1-propylcyclohexane-1-(2,3),3,4-tetracarboxylic dianhydride, 1,3-dipropylcyclohexane-1-(2,3),3-(2,3)-tetracarboxylic dianhydride, dicyclohexyl-3,4,3′,4′-tetracarboxylic dianhydride, bicyclo[2.2.1]heptane-2,3,5,6-tetracarboxylic dianhydride, bicyclo[2.2.2]octane-2,3,5,6-tetracarboxylic dianhydride, and bicyclo[2.2.2]oct-7-ene-2,3,5,6-tetracarboxylic dianhydride. These tetracarboxylic dianhydrides, that is, non-aromatic tetracarboxylic dianhydrides, account for preferably 30 mol % or less, more preferably 20 mol % or less of the total acid anhydrides.

The solvent used when polyamic acids are obtained by reacting (polymerizing) aromatic tetracarboxylic acids with aromatic diamines is not particularly limited as long as it dissolves both the monomers as raw materials and the produced polyamic acids, but polar organic solvents are preferable, and examples thereof include N-methyl-2-pyrrolidone, N-acetyl-2-pyrrolidone, N,N-dimethylformamide, N,N-diethylformamide, N,N-dimethylacetamide, dimethyl sulfoxide, hexamethylphosphoric amide, ethyl cellosolve acetate, diethylene glycol dimethyl ether, sulfolane, and halogenated phenols. These solvents can be used singly or in mixture. The amount of solvent used is only required to be an amount sufficient to dissolve the monomers as raw materials, and a specific amount of solvent used includes an amount so that the mass of monomers in the solution in which the monomers are dissolved is usually 5% to 40% by mass, preferably 10% to 30% by mass.

As the conditions for polymerization reaction (hereinafter simply referred to as “polymerization reaction”) to obtain a polyamic acid, conventionally known conditions may be adopted, and specific examples thereof include continuous stirring and/or mixing in an organic solvent in a temperature range of 0° C. to 80° C. for 10 minutes to 30 hours. If necessary, the polymerization reaction may be divided or the temperature may be raised or lowered. In this case, the order of addition of both monomers is not particularly limited, but it is preferable to add an aromatic tetracarboxylic anhydride to a solution of an aromatic diamine. The viscosity of the polyamic acid solution obtained by a polymerization reaction is preferably 10 to 2000 Pa's, more preferably 100 to 1000 Pa's as measured using a Brookfield viscometer (25° C.) from the viewpoint of stability of solution sending.

Vacuum defoaming during the polymerization reaction is effective in producing a high-quality polyamic acid solution. The polymerization may be controlled by adding a small amount of a terminal blocking agent to the aromatic diamine before the polymerization reaction. Examples of the terminal blocking agent include compounds having a carbon-carbon double bond, such as maleic anhydride. In a case of using maleic anhydride, the amount of maleic anhydride used is preferably 0.001 to 1.0 mole per 1 mole of aromatic diamine.

In order to form the polyimide film 70 from the polyamic acid solution obtained by the polymerization reaction, a method may be adopted in which the polyamic acid solution is applied onto a support and dried to obtain a green film (self-supporting precursor film) and the green film is then subjected to a heat treatment to cause an imidization reaction. The application of the polyamic acid solution to the support includes casting from a slit die, extrusion using an extruder, and the like, but is not limited to these, and any conventionally known solution application means can be used appropriately.

The conditions for drying the polyamic acid applied onto the support to obtain a green sheet are not particularly limited, and examples of the temperature include 70° C. to 150° C., and examples of the drying time include 5 to 180 minutes. As a drying device for achieving such conditions, a conventionally known device can be adopted, and hot air, hot nitrogen, far infrared rays, high-frequency induction heating, and the like can be mentioned. Next, an imidization reaction is conducted to obtain the polyimide film 70 from the obtained green sheet. As a specific method for this, a conventionally known imidization reaction can be appropriately used. Examples thereof include a method (so-called thermal ring-closing method) in which a stretching treatment is performed using a polyamic acid solution that does not contain a ring-closing catalyst or a dehydrating agent, if necessary, and then a heat treatment is performed to conduct the imidization reaction. Examples of the heating temperature in this case include 100° C. to 500° C., and from the viewpoint of physical properties of the film, a two-stage heat treatment of performing a treatment at 150° C. to 250° C. for 3 to 20 minutes and then a treatment at 350° C. to 500° C. for 3 to 20 minutes is more preferable.

Another example of the imidization reaction is a chemical ring-closing method in which a ring-closing catalyst and a dehydrating agent are added to a polyamic acid solution and the imidization reaction is conducted by the action of the ring-closing catalyst and the dehydrating agent. In this method, after the polyamic acid solution can be applied to the support, the imidization reaction can be partly conducted to form a self-supporting film, and then the imidization can be completely conducted by heating. In this case, the conditions for partly conducting the imidization reaction are preferably heat treatment at 100° C. to 200° C. for 3 to 20 minutes, and the conditions for completely conducting the imidization reaction are preferably heat treatment at 200° C. to 400° C. for 3 to 20 minutes.

### <1.2. PTFE Film>

The resin film 7 includes a PTFE film 71 and a PTFE film 72. Since the resin film 7 includes the PTFE film 71 and the PTFE film 72, the relative permittivity and dielectric loss tangent of the resin film 7 can be reduced. This is because PTFE exhibits the lowest relative permittivity and the lowest dielectric loss tangent among fluororesins such as tetrafluoroethylene-perfluoroalkyl vinyl ether copolymer (namely, PFA) and tetrafluoroethylene-hexafluoropropylene copolymer (namely, FEP).

The PTFE film 71 is laminated directly on the polyimide film 70. Since the PTFE film 71 is laminated directly on the polyimide film 70, the relative permittivity and dielectric loss tangent of the resin film 7 can be further reduced. This will be explained. If the PTFE film 71 and the polyimide film 70 are bonded together with an adhesive, it is considered that the relative permittivity and dielectric loss tangent are increased by the adhesive. In contrast, according to the present embodiment, the PTFE film 71 is directly laminated on the polyimide film 70, that is, the PTFE film 71 is bonded to the polyimide film 70 without an adhesive. Therefore, it is possible to avoid an increase in the relative permittivity and dielectric loss tangent that may be caused by the adhesive. Hence, the relative permittivity and dielectric loss tangent of the resin film 7 can be further reduced. Meanwhile, the PTFE film 72 is also laminated directly on the polyimide film 70. Since the PTFE film 72 is laminated directly on the polyimide film 70, the relative permittivity and dielectric loss tangent of the resin film 7 can be further reduced.

Of both surfaces of the PTFE film 71, at least the surface facing the polyimide film 70 is preferably subjected to surface modification. As this surface is subjected to surface modification, it is possible to increase the peel strength when the PTFE film 71 is peeled off from the polyimide film 70, and therefore, undesired peeling off of the PTFE film 71 can be further suppressed. Both surfaces of the PTFE film 71 may be subjected to surface modification.

Of both surfaces of the PTFE film 72, at least the surface facing the polyimide film 70 is preferably subjected to surface modification. As this surface is subjected to surface modification, it is possible to increase the peel strength when the PTFE film 72 is peeled off from the polyimide film 70, and therefore, undesired peeling off of the PTFE film 72 can be further suppressed. Both surfaces of the PTFE film 72 may be subjected to surface modification.

The thickness of the PTFE film 71 and the PTFE film 72 is preferably 5 μm or more, more preferably 10 μm or more, still more preferably 15 μm or more, still more preferably 20 μm or more. Meanwhile, the thickness of the PTFE film 71 is preferably 100 μm or less, more preferably 70 μm or less, still more preferably 60 μm or less, still more preferably 50 μm or less. The thickness of the PTFE film 71 and the thickness of the PTFE film 72 can be independent of each other. Hence, the thicknesses of the two may be the same as or different from each other.

It may go without saying that the PTFE film 71 and the PTFE film 72 contain polytetrafluoroethylene, namely, PTFE.

### <1.3. Physical Properties, Uses and the Like of Resin Film>

In the resin film 7, the peel strength when the PTFE film 71 is peeled from the polyimide film 70 is 0.5 N/mm or more. Since the peel strength is 0.5 N/mm or more, undesired peeling off of the PTFE film 71 can be suppressed. Therefore, it is possible to suppress peeling off of the PTFE film 71 from the polyimide film 70 that may occur by the impact that the resin film 7 may receive and a change in temperature, a change in humidity, and the like. The peel strength is preferably 0.6 N/mm or more, more preferably 0.7 N/mm or more, still more preferably 0.8 N/mm or more, still more preferably 0.9 N/mm or more. Meanwhile, the peel strength may be, for example, 2.0 N/mm or less, or 1.5 N/mm or less, 1.4 N/mm or less, 1.3 N/mm or less, or 1.2 N/mm or less.

In the resin film 7, the peel strength when the PTFE film 72 is peeled off from the polyimide film 70 is preferably 0.5 N/mm or more, more preferably 0.6 N/mm or more, still more preferably 0.7 N/mm or more, still more preferably 0.8 N/mm or more, still more preferably 0.9 N/mm or more. When the peel strength is 0.5 N/mm or more, undesired peeling off of the PTFE film 72 can be suppressed. Therefore, it is possible to suppress peeling off of the PTFE film 72 from the polyimide film 70 that may occur by the impact that the resin film 7 may receive and a change in temperature, a change in humidity, and the like. Meanwhile, the peel strength may be, for example, 2.0 N/mm or less, or 1.5 N/mm or less, 1.4 N/mm or less, 1.3 N/mm or less, or 1.2 N/mm or less.

In the resin film 7, the relative permittivity at 28 GHz is preferably 3.0 or less, more preferably 2.8 or less, still more preferably 2.6 or less, still more preferably 2.55 or less, still more preferably 2.50 or less.

In the resin film 7, the dielectric loss tangent at 28 GHz is preferably 0.006 or less, more preferably 0.005 or less, still more preferably 0.004 or less. The dielectric loss tangent at 28 GHz may be 0.0035 or less, or 0.0030 or less.

The coefficient of linear thermal expansion of the resin film 7 at 50° C. to 200° C. is preferably 30 ppm/° C. or less, more preferably 28 ppm/° C. or less, still more preferably 25 ppm/° C. or less. This is because peeling off of the metal foil from the resin film 7 can be further suppressed as the coefficient of linear thermal expansion of the resin film 7 is closer to the coefficient of linear thermal expansion of the metal foil (copper foil, as an example). Meanwhile, the coefficient of linear thermal expansion of the resin film 7 at 50° C. to 200° C. may be, for example, 5 ppm/° C. or more.

The thickness of the resin film 7 is preferably 5 μm or more, more preferably 10 μm or more. The thickness of the resin film 7 may be 20 μm or more, 30 μm or more, 40 μm or more, 50 μm or more, or 60 μm or more. Meanwhile, the thickness of the resin film 7 is preferably 150 μm or less, more preferably 100 μm or less.

In 100% of the total thickness of the PTFE film 71, the polyimide film 70, and the PTFE film 72, the total thickness of the PTFE film 71 and the PTFE film 72 is preferably 60% or more, more preferably 70% or more, still more preferably 75% or more. When the total thickness of the PTFE film 71 and the PTFE film 72 is 60% or more, the relative permittivity and dielectric loss tangent of the resin film 7 can be further reduced. Meanwhile, from the viewpoint of dimensional stability of the resin film 7, the total thickness of the PTFE film 71 and the PTFE film 72 is preferably 90% or less, more preferably 85% or less, still more preferably 80% or less.

The resin film 7 can be suitably used for producing printed wiring boards, metal-clad laminates, and the like. This is because it is possible to produce a printed wiring board having excellent dimensional stability and reduced transmission loss by the resin film 7. An example of the printed wiring board can be a flexible printed wiring board (for example, a single-sided flexible printed wiring board, a double-sided flexible printed wiring board, or a multi-layer flexible printed wiring board).

### <2. Method for Producing Resin Film>

The method for producing the resin film 7 includes a step of subjecting the PTFE film 71 and the PTFE film 72 to surface modification (hereinafter, sometimes referred to as “step A”); a step of subjecting the polyimide film 70 to surface modification (hereinafter, sometimes referred to as “step B”); and a step of performing thermocompression bonding on these films in a state where the surface subjected to surface modification of the PTFE film 71 faces the polyimide film 70 and the surface subjected to surface modification of the PTFE film 72 faces the polyimide film 70 (hereinafter, sometimes referred to as “step C”). Either step A or step B may be carried out first, or these steps may be carried out in parallel.

### <2.1. Step A>

In step A, surface modification is performed on the PTFE film 71 and the PTFE film 72. Step A includes a step of performing plasma treatment on the surface of the PTFE film 71 (hereinafter, sometimes referred to as “step A1”); and a step of performing plasma treatment on the surface of the PTFE film 72 (hereinafter sometimes referred to as “step A2”). Step A1 and step A2 may be carried out separately, or may be carried out together using one plasma treatment apparatus. In a case where step A1 and step A2 are carried out separately, these may be carried out in parallel, or one may be carried out first.

### <2.1.1. Step A1—Step of Performing Plasma Treatment on Surface of PTFE Film 71>

In step A1, plasma treatment is performed on the surface of the PTFE film 71. This makes it possible to break the carbon-fluorine bond in the PTFE molecule. Examples of the plasma treatment include vacuum plasma treatment (that is, low-pressure plasma treatment) and atmospheric pressure plasma treatment. Among these, atmospheric pressure plasma treatment is preferable since it is possible to heat the surface of the PTFE film 71. In this specification, “atmospheric pressure plasma treatment” means plasma treatment at 700 hPa to 1300 hPa.

It is preferable to utilize a dielectric barrier discharge for the plasma treatment. By utilizing a dielectric barrier discharge, a glow discharge can be stably generated at atmospheric pressure (that is, 700 hPa to 1300 hPa).

The pressure for the plasma treatment may be, for example, 700 hPa or more, 800 hPa or more, 900 hPa or more, 950 hPa or more, or 1000 hPa or more. The pressure for the plasma treatment may be, for example, 1300 hPa or less, 1200 hPa or less, or 1100 hPa or less.

In step A1, plasma treatment is performed on the surface of the PTFE film 71 at an oxygen concentration of less than 0.5% by volume. Since the plasma treatment is performed at an oxygen concentration of less than 0.5% by volume, it is possible to avoid inhibition of carbon-carbon bond formation by oxygen (that is, “oxygen inhibition”), and therefore, the surface hardness of the PTFE film 71 can be improved. Hence, the adhesive properties of the PTFE film 71 to the polyimide film 70, that is, the peel strength, can be improved. The oxygen concentration may be, for example, 0.4% by volume or less, 0.3% by volume or less, 0.2% by volume or less, or 0.1% by volume or less.

In step A1, the temperature of the surface of the PTFE film 71 is 180° C. or more. Since the plasma treatment is performed at 180° C. or more, it is possible to improve the mobility of PTFE molecules on the surface of the PTFE film 71, and therefore, a PTFE molecule having the carbon atom of a carbon-fluorine bond broken by irradiation with plasma can be effectively bonded to another PTFE molecule having a carbon atom similarly broken. In other words, it is possible to actively promote the formation of carbon-carbon bonds between PTFE molecules. In other words, it is possible to actively promote the crosslinking reaction. Hence, the surface hardness of the PTFE film 71 can be improved (this may be rephrased as that the weakened layer on the surface of the PTFE film 71 can be repaired or removed). As a result, the adhesive properties of the PTFE film 71 to the polyimide film 70, that is, the peel strength, can be improved. The temperature of the surface of the PTFE film 71 may be 190° C. or more, 195° C. or more, 200° C. or more, or 205° C. or more. Meanwhile, the temperature of the surface of the PTFE film 71 may be, for example, 320° C. or less, 280° C. or less, 260° C. or less, 240° C. or less, or 220° C. or less. The temperature of the surface of the PTFE film 71 can be adjusted, for example, by the power input to a high frequency power source to be described later, heating using a halogen heater to be described later, and the like.

The time during which the temperature of the surface of the PTFE film 71 is 180° C. or more is preferably 30 seconds or more, more preferably 100 seconds or more, still more preferably 200 seconds or more, still more preferably 300 seconds or more. This may be 400 seconds or more, or 500 seconds or more. Meanwhile, the time during which the temperature of the surface of the PTFE film 71 is 180° C. or more may be 6000 seconds or less, 3000 seconds or less, 2000 seconds or less, or 1000 seconds or less.

In order to generate plasma, for example, a high frequency power source having a frequency of applied voltage of 50 Hz to 2.45 GHz can be used. The output power density, that is, the output power per unit area, cannot be generally stated, but if forced to say, is preferably 15 W/cm² or more and 40 W/cm² or less.

In a case where a pulsed output is used, the pulse modulation frequency is preferably 1 kHz to 50 kHz, more preferably 5 kHz to 30 kHz. The pulse duty is preferably 5% to 99%, more preferably 15% to 80%, still more preferably 25% to 70%.

As the counter electrode, a cylindrical or flat metal having at least one side covered with a dielectric material can be used. The distance between opposing electrodes cannot be generally stated, but if forced to say, is preferably 5 mm or less, more preferably 3 mm or less, still more preferably 2 mm or less, still more preferably 1 mm or less from the viewpoint of plasma generation and heating. The lower limit of the distance between opposing electrodes may be, for example, 0.2 mm or more, 0.4 mm or more, or 0.5 mm or more.

As the gas used to generate plasma, for example, a rare gas such as helium, argon, or neon or a reactive gas such as oxygen, nitrogen, or hydrogen can be used. It is preferable to use only non-polymerizable gases as the gas. Among these gases, only one or two or more rare gases may be used. A mixed gas of one or two or more rare gases with an appropriate amount of one or two or more reactive gases may be used. In a case where a dielectric barrier discharge is utilized, helium is preferable since it is easy to obtain a glow discharge and the discharge initiation voltage is low. In a case where a dielectric barrier discharge is utilized, argon and nitrogen are preferable since it is easy to obtain a glow discharge and these are inexpensive.

Regarding the generation of plasma, plasma may be generated under a condition in which the gas atmosphere is controlled using a chamber, or plasma may be generated under a condition completely open to the atmosphere in which a rare gas is allowed to flow through the electrode portion.

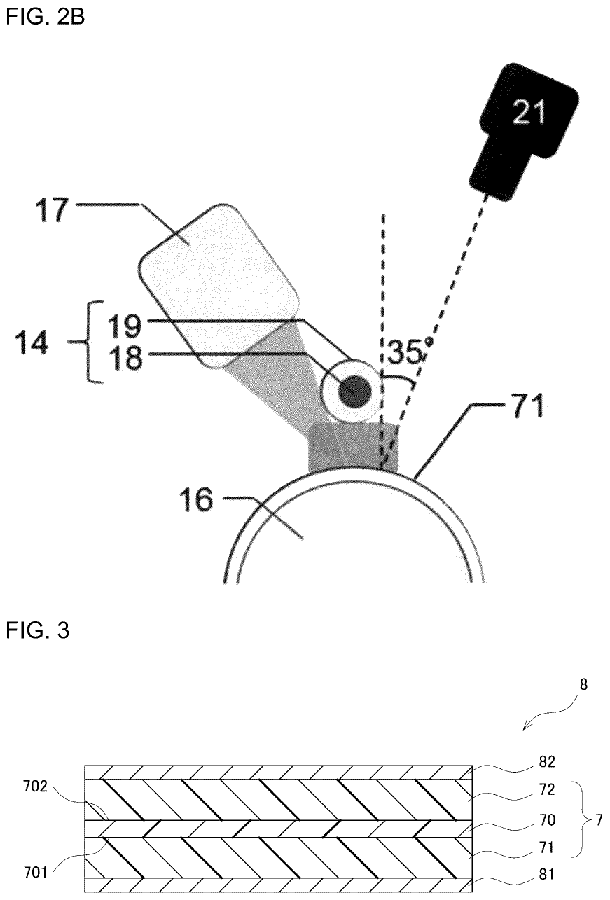

Hereinafter, an example of the plasma treatment according to step A1 will be described with reference to FIGS. 2A and 2B.

The method for surface modification of the PTFE film 71 using an atmospheric pressure plasma treatment apparatus A illustrated in FIG. 2A is as follows. First, the PTFE film 71 is washed with an organic solvent such as acetone and water such as ultrapure water, if necessary. Next, as illustrated in FIG. 2B, the PTFE film 71 is disposed on the sample holder of a rotating stage 16 in a chamber 12, the air inside the chamber 12 is sucked through a vacuum pumping system 13 to reduce the pressure using a suction device (not illustrated), and a gas for generating plasma is supplied into the chamber 12 (see the arrow in FIG. 2A). This brings the interior of the chamber 12 to atmospheric pressure. The PTFE film 71 is not illustrated in FIG. 2A, but is illustrated only in FIG. 2B. Atmospheric pressure is not required to be exactly 1013 hPa, but is only required to be in the range of 700 to 1300 hPa.

Using an apparatus such as that illustrated in FIG. 2A, plasma treatment can be performed by setting the oxygen concentration in the vicinity of the surface (region irradiated with plasma) of the PTFE film 71 to less than 0.5% by volume.

Next, the height of an electrode lifting mechanism 15 (the vertical direction in FIG. 2A) is adjusted, and an electrode 14 is moved to a desired position. By adjusting the height of the electrode lifting mechanism 15, the distance between the electrode 14 and the surface (upper surface) of the PTFE film 71 can be adjusted. The distance between the electrode 14 and the surface of the PTFE film 71 is preferably 5 mm or less, more preferably 2 mm or less. In particular, in a case where the surface temperature of the PTFE film 71 is set to a specific range by natural temperature increase due to plasma treatment, the distance is particularly preferably 1.0 mm or less. Since the PTFE film 71 is moved by the rotation of the rotating stage 16, it goes without saying that the electrode 14 must not come into contact with the PTFE film 71.

By rotating the rotating stage 16, a desired portion of the surface of the PTFE film 71 can be irradiated with plasma. The rotating speed of the rotating stage 16 is preferably 1 mm/sec to 3 mm/sec, but may be outside this range. The time for irradiation of the PTFE film 71 with plasma can be adjusted, for example, by varying the rotating speed of the rotating stage 16 or by repeatedly rotating the rotating stage 16 a desired number of times.

As a high frequency power source 10 is operated while the PTFE film 71 is moved by moving the rotating stage 16, plasma is generated between the electrode 14 and the rotating stage 16, and a desired area on the surface of the PTFE film 71 is irradiated with the plasma. At this time, by using, for example, the high frequency power source 10 having the frequency of applied voltage and output power density as described above as the high frequency power source 10 as well as using an alumina-covered copper electrode and an aluminum alloy sample holder, a glow discharge under a dielectric barrier discharge condition can be realized. Therefore, peroxide radicals can be generated stably on the surface of the PTFE film 71. The introduction of peroxide radicals is performed as the formation of dangling bonds due to defluorination of the surface of the PTFE film 71 is induced by radicals, electrons, ions and the like contained in the plasma, and these are exposed to air remaining in the chamber or clean air after plasma treatment to react with a water component and the like in the air. In addition to peroxide radicals, hydrophilic functional groups such as hydroxyl groups and carbonyl groups may be spontaneously formed on the dangling bonds.

The intensity of the plasma with which the surface of the PTFE film 71 is irradiated can be appropriately adjusted by various parameters of the high frequency power source 10, the distance between the electrode 14 and the surface of the PTFE film 71, and the like. The surface of the PTFE film 71 may be set to a specific temperature range by adjusting the cumulative irradiation time of the surface of the PTFE film 71 according to the output power density. For example, in a case where the frequency of the applied voltage is 5 to 30 MHz, the distance between the electrode 14 and the surface of the PTFE film 71 is 0.5 mm to 2.0 mm, and the output power density is 15 W/cm² to 30 W/cm², the cumulative irradiation time of the surface of the PTFE film 71 is preferably 50 seconds to 3300 seconds, more preferably 250 seconds to 3300 seconds, still more preferably 550 seconds to 2400 seconds. The time for irradiation with plasma means the cumulative time during which the surface of the PTFE film 71 is irradiated with plasma. The surface temperature of the PTFE film 71 is only required to be 180° C. or more during at least a portion of the time for irradiation with plasma. The surface temperature of the PTFE film 71 is preferably 180° C. or more for at least ½ of the time for irradiation with plasma, more preferably 180° C. or more for at least ⅔ of the time for irradiation with plasma. In any aspect, by setting the surface temperature of the PTFE film 71 to the above range, the mobility of the PTFE molecules on the surface of the PTFE film 71 can be improved, the probability that the carbon atom of the carbon-fluorine bond in the PTFE molecule broken by the plasma bonds with the carbon atom of another PTFE molecule generated in the same manner to form a carbon-carbon bond is significantly increased, and the surface hardness can be improved.

A heating means for heating the PTFE film 71 can be provided separately. As illustrated in FIG. 2B, a heat ray irradiation device such as a halogen heater 17 may be disposed in the vicinity of the electrode 14 in order to directly heat the surface of the PTFE film 71. In order to increase the environmental temperature in the chamber 12, a heating device for heating the above-mentioned gas in the chamber 12 and a circulation device equipped with a stirring blade or the like for circulating the heated gas in the chamber 12 may be disposed in the chamber 12. In order to heat the PTFE film 71 from the lower surface side, a heating means may be disposed on the rotating stage 16. Of course, these may be combined. It is preferable to preheat the PTFE film 71 before the high frequency power source 10 is operated so that the temperature reaches a desired temperature during irradiation with plasma.

The surface temperature of the PTFE film 71 during the plasma treatment can be measured using a radiation thermometer 21 as illustrated in FIG. 2B. The surface temperature of the PTFE film 71 may be measured using a temperature measuring sticker.

The description of an example of plasma treatment based on FIGS. 2A and 2B is as above.

The surface of the PTFE film 71 subjected to plasma treatment can have a hydrophilic functional group. Examples of the hydrophilic functional group include peroxide radicals, hydroxyl groups, carbonyl groups, and carboxyl groups. Regarding the generation of peroxide radicals, the carbon atom of the carbon-fluorine bond broken by irradiation with plasma may react with oxygen that may be present in the surroundings during irradiation with plasma, thereby generating peroxide radicals. Peroxide radicals may be generated as the carbon atom of the carbon-fluorine bond broken by irradiation with plasma is exposed to the atmospheric air after the plasma treatment. Of course, the carbon atom of the carbon-fluorine bond broken by irradiation with plasma may react with oxygen that may be present in the surroundings during irradiation with plasma, thereby generating peroxide radicals. Peroxide radicals may be generated as the carbon atom of the carbon-fluorine bond broken by irradiation with plasma is exposed to the atmospheric air after the plasma treatment.

### <2.2.2. Step A2-Step of Performing Plasma Treatment on Surface of PTFE Film 72>

The explanation of step A2 overlaps with the explanation of step A1 and will be thus omitted. Hence, the explanation of step A1 can also be treated as the explanation of step A2.

### <2.2. Step B-Step of Performing Surface Modification of Polyimide Film 70>

In step B, surface modification of the polyimide film 70, that is, a surface activation treatment is performed. Step B can include a step of modifying a surface 701 of the polyimide film 70 (hereinafter, sometimes referred to as “step B1”); and a step of modifying a surface 702 of the polyimide film 70 (hereinafter, sometimes referred to as “step B2”). Step B1 and step B2 may be carried out together or separately. In a case where step B1 and step B2 are carried out separately, these may be carried out in parallel, or one may be carried out first.

For surface activation, the polyimide film 70 may be subjected to surface treatment by a dry method or a wet method. Examples of the surface treatment by a dry method include plasma treatment, treatment of irradiating the surface with active energy rays such as ultraviolet rays, electron beams, and X rays, corona treatment, flame treatment, and Itro treatment. Meanwhile, examples of the surface treatment by a wet method include treatment of bringing the surface of the polymer film into contact with an acid and/or alkali solution. Among these, corona treatment and plasma treatment are more preferable since hydrophilization can be achieved by operation with relatively little burden.

In a case where plasma treatment is performed for surface modification of the polyimide film 70, examples of the plasma treatment include vacuum plasma treatment (that is, low-pressure plasma treatment) and atmospheric pressure plasma treatment. As the gas used to generate plasma, for example, a rare gas such as helium, argon, or neon or a reactive gas such as oxygen, nitrogen, or hydrogen can be used. Among these, oxygen is preferable since hydrophilization can be effectively achieved. Among these gases, one or two or more kinds may be used.

### <2.3. Step C-Step of Performing Thermocompression Bonding>

In step C, thermocompression bonding is performed on these films in a state where the surface subjected to surface modification of the PTFE film 71 faces the polyimide film 70 and the surface subjected to surface modification of the PTFE film 72 faces the polyimide film 70. In other words, these are stacked and then subjected to thermocompression bonding.

The heating temperature during thermocompression bonding may be, for example, 200° C. to 400° C. The pressure may be, for example, 0.1 MPa to 20 MPa. The time for thermocompression bonding may be, for example, 5 to 40 minutes. The thermocompression bonding may be performed using a hot press machine. It is preferable to remove air present at the interface by performing vacuuming to about 10 Pa before the thermocompression. In other words, it is preferable to perform the thermocompression bonding at reduced pressure.

### <3. Metal-Clad Laminate and Printed Wiring Board>

As illustrated in FIG. 3, a metal-clad laminate 8 of the present embodiment includes a resin film 7, a metal foil 81, and a metal foil 82. In the metal-clad laminate 8, the metal foil 81, the resin film 7, and the metal foil 82 are arranged in this order in the thickness direction of the metal-clad laminate 8. Specifically, the metal foil 81, a PTFE film 71, a polyimide film 70, a PTFE film 72, and the metal foil 82 are arranged in this order in the thickness direction of the metal-clad laminate 8.

The metal foil 81 is provided on the PTFE film 71. Examples of the method for providing the metal foil 81 on the PTFE film 71 include a method in which a monomer-polymerized layer is formed on the PTFE film 71 and then the metal foil 81 is directly or indirectly formed on the monomer-polymerized layer (see, for example, Patent Document 4, that is, JP-A-2012-233038). The monomer-polymerized layer can be a layer that is formed as a monomer is polymerized by irradiation with plasma. The monomer contains a reactive unsaturated bonding group. An example of the monomer is an acrylic monomer. The acrylic monomer is preferably acrylic acid or a derivative thereof, or methacrylic acid or a derivative thereof. Acrylic acid and methacrylic acid are preferable since gasification is easy. Meanwhile, examples of the method providing the metal foil 81 on the PTFE film 71 also include a method in which metal sodium is dissolved in liquid ammonia, then this solution is brought into contact with the PTFE film 71, and the metal foil 81 is formed directly or indirectly on the surface modified with this solution. Examples thereof also include a method in which metal sodium is further dissolved in an ether solvent in which naphthalene is dissolved, then this solution is brought into contact with the PTFE film 71, and the metal foil 81 is formed directly or indirectly on the surface modified with this solution. Examples thereof also include a method in which a slurry in which atomized metal sodium is dispersed in oil is brought into contact with the PTFE film 71 and the metal foil 81 is formed directly or indirectly on the surface modified with this solution.

The metal foil 82 is provided on the PTFE film 72. The explanation of the method for providing the metal foil 82 on the PTFE film 72 overlaps with the explanation of the method for providing the metal foil 81 on the PTFE film 71 and will be thus omitted. Hence, the explanation of the method for providing the metal foil 81 on the PTFE film 71 can also be treated as the explanation of the method for providing the metal foil 82 on the PTFE film 72.

The thickness of the metal foil 81 may be, for example, 1 μm or more, 2 μm or more, or 3 μm or more. Meanwhile, the thickness of the metal foil 81 may be, for example, 30 μm or less, 20 μm or less, 15 μm or less, or 10 μm or less.

Examples of the material for the metal foil 81 include copper, stainless steel, iron, nickel, beryllium, aluminum, zinc, indium, silver, gold, tin, zirconium, tantalum, titanium, lead, magnesium, manganese, and alloys thereof. Among these, copper and a copper alloy are preferable, and copper is more preferable.

The explanation of the metal foil 82 overlaps with the explanation of the metal foil 81 and will be thus omitted. Hence, the explanation of the metal foil 81 can also be treated as the explanation of the metal foil 82.

As described above, the material for the metal foil 81 and the metal foil 82 is preferably copper and a copper alloy. In other words, the metal-clad laminate 8 is preferably a copper-clad laminate.

### 4. Various Modifications can be Made to the Present Embodiment

Various modifications can be made to the embodiment described above. For example, one or more of the following modified examples can be selected and modifications can be made to the embodiment described above.

In the embodiment described above, the configuration in which the resin film 7 includes both the PTFE film 71 and the PTFE film 72 has been described. However, the present embodiment is not limited to this configuration. The resin film 7 may not include the PTFE film 72.

In the embodiment described above, the configuration in which the polyimide film 70 is subjected to surface modification has been described. However, the present embodiment is not limited to this configuration. In other words, the polyimide film 70 may not be subjected to surface modification.

In the embodiment described above, the configuration in which the resin film 7 is used to produce a printed wiring board and a metal-clad laminate has been described. However, the present embodiment is not limited to this configuration. In other words, the resin film 7 may be used for other purposes.

In the embodiment described above, the configuration in which the PTFE film 71, the polyimide film 70, and the PTFE film 72 are stacked in this order and then thermocompression-bonded has been described. However, the present embodiment is not limited to this configuration. For example, the PTFE film 71 and the polyimide film 70 may be thermocompression-bonded, and then the polyimide film 70 and the PTFE film 72 may be thermocompression-bonded.

In the embodiment described above, the configuration in which the polyimide film 70 and the PTFE film 71 are thermocompression-bonded in order to directly laminate these. However, the present embodiment is not limited to this configuration. For example, a polyamic acid solution for forming the polyimide film 70 may be applied to the surface subjected to surface modification of the PTFE film 71, and drying and heat treatment (imidization) may be performed.

In the embodiment described above, the configuration in which the polyimide film 70 and the PTFE film 72 are thermocompression-bonded in order to directly laminate these. However, the present embodiment is not limited to this configuration. For example, a polyamic acid solution for forming the polyimide film 70 may be applied to the surface of the PTFE film 72 that has undergone surface modification, and drying and heat treatment (imidization) may be performed.

In the embodiment described above, the configuration in which the metal-clad laminate 8 includes both the metal foil 81 and the metal foil 82 has been described. However, the present embodiment is not limited to this configuration. The metal-clad laminate 8 may not include the metal foil 82.

### EXAMPLES

Hereinafter, the present invention will be more specifically described by reference to Examples and Comparative Examples. Hereinafter, “parts” means “parts by mass” and “%” means “% by mass” unless otherwise stated.

### <1. Polyimide Film>

A polyimide film measuring 150 mm×150 mm was cut out from Xenomax F38 (a polyimide film having a thickness of 38 μm) manufactured by Xenomax-Japan Co., Ltd. The polyimide film measuring 150 mm×150 mm was set in a plasma treatment machine manufactured by Nippo Electronics Co., Ltd., evacuation to a vacuum was performed, then oxygen gas was introduced, and a discharge was generated to perform a vacuum plasma treatment. The conditions for the vacuum plasma treatment were a degree of vacuum of 3×10 Pa, a gas flow rate of 1.5 SLM (standard liter per minute), and a discharge power of 12 KW.

### <2. PTFE Film>

### <2.1. Cleaning>

A PTFE film measuring 450 mm×700 mm was cut out from NITOFLON No. 900UL (a PTFE film having a thickness of 50 μm) manufactured by NITTO DENKO CORPORATION. The PTFE film measuring 450 mm×700 mm was immersed in acetone and then subjected to ultrasonic cleaning for 1 minute. Next, the PTFE film was immersed in pure water and then subjected to ultrasonic cleaning for 1 minute. Nitrogen gas having a purity of 99% or more was sprayed onto the PTFE film taken out of the pure water using an air gun. The pure water attached to the PTFE film was thus blown off.

### <2.2. Thermally Assisted Plasma Treatment>

The surface of the cleaned PTFE film was modified with plasma using a plasma generator (manufactured by MEISYO KIKO Co., Ltd., product name K2X02L023) illustrated in FIGS. 2A and 2B. Specifically, the plasma treatment (hereinafter, sometimes referred to as “thermally assisted plasma treatment”) was performed using the following apparatus and procedure.

As the high frequency power source for the plasma generator, a power source device having a frequency of applied voltage of 13.56 MHz was used. As the electrode, an electrode having a structure in which a copper tube having an inner diameter of 1.8 mm, an outer diameter of 3 mm, and a length of 165 mm was covered with an alumina tube having an outer diameter of 5 mm, a thickness of 1 mm, and a length of 145 mm was used. As the rotating stage, a cylindrical aluminum alloy rotating stage having a diameter of 50 mm and a width of 3.4 cm was used. The PTFE film was placed on the top of the rotating stage and then fixed with a sample holder, and the position of the electrode was adjusted so that the distance between the PTFE film surface and the electrode was 1.0 mm.

The chamber was sealed, the pressure was reduced to 10 Pa using a rotary pump, and then helium gas was introduced into the chamber until the pressure inside the chamber reached atmospheric pressure (specifically, 1013 hPa). Next, the high frequency power source was set so that the output power density was 19.1 W/cm² as well as the rotating stage was set so that the PTFE film moved directly under the electrode by 30 mm at 2 mm/sec in the length direction of the PTFE film. Thereafter, the high frequency power source was turned on, and irradiation with plasma was performed for 600 seconds in an area of 1.0 cm width×3.4 cm length while the rotating stage was rotated and moved. At this time, the time for irradiation with plasma was adjusted by the number of reciprocating movements of the rotating stage. Specifically, since it takes 30 seconds per one reciprocating movement, the number of reciprocating movements of the rotating stage was set to 20.

During the plasma treatment, the oxygen concentration in the vicinity of the PTFE film surface was measured using a zirconia-type oxygen analyzer LC-300 manufactured by Toray Engineering Co., Ltd. The oxygen concentration was 25.7 ppm. Hence, the oxygen concentration was significantly below 0.5% by volume. During the plasma treatment, the surface temperature of the PTFE film was measured using a radiation thermometer (FT-H40K and FT-50A, manufactured by KEYENCE CORPORATION). The surface temperature of the PTFE film was 203° C.

### <2.3. Comparative Plasma Treatment>

The plasma treatment (hereinafter, sometimes referred to as “comparative plasma treatment”) was performed on the surface of the cleaned PTFE film using the following apparatus and procedure.

As the room temperature atmospheric pressure plasma treatment apparatus, FPE20 manufactured by FUJI MACHINERY CO., LTD. was used. The output was 900 W, and the gases used were N₂ gas at 29.7 L/min and air at 0.3 L/min. The PTFE film was placed on the top of the stage and then fixed with a sample holder, and was adjusted so that the distance between the PTFE film surface and the electrode was 10 mm. The stage was set so that the PTFE film moved directly under the electrode at 8 mm/sec in the length direction of the PTFE film, and then irradiation with plasma was performed in a single pass (that is, by a method in which the PTFE film passed directly under the electrode one time).

### <3. PFA Film>

### <3.1. Cleaning>

A PFA film measuring 450 mm×700 mm was cut out from Fluon+EA-2000 (thickness 25 μm) manufactured by AGC Inc. The PFA film measuring 450 mm×700 mm was immersed in acetone and then subjected to ultrasonic cleaning for 1 minute. Next, the PFA film was immersed in pure water and then subjected to ultrasonic cleaning for 1 minute. Nitrogen gas having a purity of 99% or more was sprayed onto the PFA film taken out of the pure water using an air gun. The pure water attached to the PFA film was thus blown off.

### <3.2. Thermally Assisted Plasma Treatment>

The thermally assisted plasma treatment was performed in the same manner as that previously described, except that the cleaned PFA film was used instead of the cleaned PTFE film.

### <3.3. Comparative Plasma Treatment>

The comparative plasma treatment was performed in the same manner as that previously described, except that the cleaned PFA film was used instead of the cleaned PTFE film.

### <4. Fabrication of Bilayer Film>

### <4.1. Fabrication of Bilayer Film According to Example 1>

The PTFE film and the polyimide film were compression-bonded at 320° C., 13 MPa, and atmospheric pressure (that is, without vacuuming) for 10 minutes in a state where the surface subjected to thermally assisted plasma treatment of the PTFE film faced the plasma-treated surface of the polyimide film. A bilayer film was thus obtained.

### <4.2. Fabrication of Bilayer Film According to Comparative Example 1>

A bilayer film was fabricated in the same manner as in Example 1, except that a polyimide film not subjected to plasma treatment was used instead of the plasma-treated polyimide film as well as a PTFE film not subjected to plasma treatment was used instead of the PTFE film subjected to thermally assisted plasma treatment.

### <4.3. Fabrication of Bilayer Film According to Comparative Example 2>

A bilayer film was fabricated in the same manner as in Example 1, except that a PTFE film not subjected to plasma treatment was used instead of the PTFE film subjected to thermally assisted plasma treatment.

### <4.4. Fabrication of Bilayer Film According to Comparative Example 3>

A bilayer film was fabricated in the same manner as in Example 1, except that a PTFE film subjected to comparative plasma treatment was used instead of the PTFE film subjected to thermally assisted plasma treatment.

### <4.5. Fabrication of Bilayer Film According to Comparative Example 4>

The PFA film and the polyimide film were compression-bonded at 340° C., 3 MPa, and atmospheric pressure (that is, without vacuuming) for 20 minutes in a state where the surface subjected to thermally assisted plasma treatment of the PFA film faced the plasma-treated surface of the polyimide film. A bilayer film was thus obtained.

### <4.6. Fabrication of Bilayer Film According to Comparative Example 5>

A bilayer film was fabricated in the same manner as in Comparative Example 4, except that a PFA film not subjected to plasma treatment was used instead of the PFA film subjected to thermally assisted plasma treatment.

### <4.7. Fabrication of Bilayer Film According to Comparative Example 6>

A bilayer film was fabricated in the same manner as in Comparative Example 4, except that a PFA film subjected to comparative plasma treatment was used instead of the PFA film subjected to thermally assisted plasma treatment.

### <5. Measurement of Peel Strength>

A 90-degree peel test was conducted using the bilayer film to determine the peel strength. Specifically, the polyimide film of the bilayer film was fixed to two stainless steel rods with an adhesive, then the gripping edge of the fluororesin film of the bilayer film (that is, PTFE film or PFA film) was clamped in the upper chuck, and the fluororesin film was then pulled up in a direction perpendicular to the polyimide film. The load cell was 1 kN and the tensile speed was 60 mm/min. The force required to peel off the fluororesin film from the polyimide film, that is, the peel force (unit: N) was divided by the sample width (unit: mm) to calculate the peel strength (unit: N/mm). In the 90-degree peel test, a digital force gauge (ZP-200N, manufactured by IMADA Co., Ltd.) and an electric stand (MX-500N, manufactured by IMADA Co., Ltd.) were used. The measurement results of peel strength are presented in Table 1.

TABLE 1

| | | | | Peel |
|---|---|---|---|---|
| | | | | strength |
| | PI film | PTFE film | PFA Film | N/mm |
| Example 1 | With plasma | Thermally | — | 1.2 |
| | treatment | assisted | | |
| | | plasma | | |
| | | treatment | | |
| Comparative | Without | Without | — | 0.0 |
| Example 1 | treatment | treatment | | |
| Comparative | With plasma | Without | — | 0.0 |
| Example 2 | treatment | treatment | | |
| Comparative | With plasma | Comparative | — | 0.1 |
| Example 3 | treatment | plasma | | |
| | | treatment | | |
| Comparative | With plasma | — | Thermally | 0.1 |
| Example 4 | treatment | | assisted | |
| | | | plasma | |
| | | | treatment | |
| Comparative | With plasma | — | Without | 1.3 |
| Example 5 | treatment | | treatment | |
| Comparative | With plasma | — | Comparative | 1.2 |
| Example 6 | treatment | | plasma | |
| | | | treatment | |

In this table, PI film means a polyimide film. For the PI film, “without treatment” means that vacuum plasma treatment was not performed.

Meanwhile, for the PTFE and PFA films, “without treatment” means that neither the thermally assisted plasma treatment nor the comparative plasma treatment was performed.

By subjecting the PTFE film to thermally assisted plasma treatment, the peel strength could be greatly improved compared to the case where treatment was not performed (that is, neither the thermally assisted plasma treatment nor the comparative plasma treatment was performed) or the case where the comparative plasma treatment was performed (see Example 1 and Comparative Examples 2 and 3).

### <6. Fabrication of Three-Layer Film According to Example 2>

Vacuum plasma treatment was performed on both surfaces of the cleaned polyimide film (specifically, Xenomax F38 manufactured by Xenomax-Japan Co., Ltd., which is a polyimide film having a thickness of 38 μm) under the conditions described above (see “1. Polyimide film”). Meanwhile, thermally assisted plasma treatment was performed on the cleaned PTFE film (specifically, NITOFLON No. 900UL manufactured by NITTO DENKO CORPORATION, which is a PTFE film having a thickness of 50 μm) under the conditions described above (see “2.2. Thermally assisted plasma treatment”). The PTFE film subjected to thermally assisted plasma treatment, the polyimide film subjected to vacuum plasma treatment, and the PTFE film subjected to thermally assisted plasma treatment were stacked and then compression-bonded at 320° C., 13 MPa, and atmospheric pressure (that is, without vacuuming) for 10 minutes. A three-layer film was thus obtained.

### <7. Fabrication of Three-Layer Film According to Example 3>

A three-layer film was fabricated in the same manner as in Example 2, except that Xenomax F12.5 (a polyimide film having a thickness of 12.5 μm) manufactured by Xenomax-Japan Co., Ltd. was used instead of Xenomax F38 and MSF-100 (a PTFE film having a thickness of 25 μm) manufactured by Chukoh Chemical Industries, Ltd. was used instead of NITOFLON No. 900UL.

### <8. Fabrication of Three-Layer Film According to Comparative Example 7>

Vacuum plasma treatment was performed on both surfaces of cleaned Xenomax F15 (a polyimide film having a thickness of 15 μm) manufactured by Xenomax-Japan Co., Ltd. under the conditions described above (see “1. Polyimide film”). A PFA film (Fluon+EA-2000 manufactured by AGC Inc.), a polyimide film subjected to vacuum plasma treatment, and a PFA film (Fluon+EA-2000 manufactured by AGC Inc.) were stacked and then compression-bonded at 340° C., 3 MPa, and atmospheric pressure for 20 minutes. A three-layer film was thus obtained.

### <9. Measurement of Permittivity and Dielectric Loss Tangent>

The permittivity and dielectric loss tangent of the three-layer film were measured by the split cylinder resonator method. Specifically, the permittivity and dielectric loss tangent were measured at 28 GHz using a network analyzer (N5290A manufactured by KEYSIGHT) and a split cylinder resonator (CR type manufactured by EM labs, Inc.). The relative permittivity was calculated from the permittivity.

### <10. Measurement of Coefficient of Linear Thermal Expansion>

The coefficient of linear thermal expansion of the three-layer film was measured using a thermomechanical analysis apparatus. Specifically, the temperature of a sample cut out from the three-layer film was increased to 250° C. at 20° C./min and then decreased to room temperature at 5° C./min. The average value from 200° C. to 50° C. during the temperature decrease was calculated as the coefficient of linear thermal expansion.
Apparatus: TMA4000S manufactured by Bruker AXS
Sample length between chucks: 10 mm
Sample width: 2 mm
Atmosphere: Nitrogen

### <11. Measurement Results>

The measurement results of physical properties of the three-layer films of Examples 2 and 3 and Comparative Example 7 are presented in Table 2.

TABLE 2

| | | | Coefficient | | |
|---|---|---|---|---|---|
| | | Thickness | of linear | | |
| | | ratio of | thermal | | |
| | Layer | fluororesin | expansion | Relative | Dielectric |
| | configuration | film % | ppm/° C. | permittivity | loss tangent |
| Example 2 | PTFE 50 μm/ | 72 | 11 | 2.54 | 0.0034 |
| | PI 38 μm/ | | | | |
| | PTFE 50 μm | | | | |
| Example 3 | PTFE 25 μm/ | 80 | 13 | 2.41 | 0.0022 |
| | PI 12.5 μm/ | | | | |
| | PTFE 25 μm | | | | |
| Comparative | PFA 25 μm/ | 77 | 16 | 2.58 | 0.0057 |
| Example 7 | PI 15 μm/ | | | | |
| | PFA 25 μm | | | | |

In this table, “thickness ratio of fluororesin film” means the total thickness of the fluororesin films when the thickness of the three-layer film is taken as 100%.

### INDUSTRIAL APPLICABILITY

The present invention can provide a resin film, a metal-clad laminate, a printed wiring board, and a method for producing a resin film, and is therefore industrially applicable.

DESCRIPTION OF REFERENCE SIGNS

7 . . . Resin film; 70 . . . Polyimide film; 71 . . . PTFE film; 72 . . . PTFE film;
701 . . . Surface of polyimide film; 702 . . . Surface of polyimide film; 8 . . . Metal-clad
laminate; 81 . . . Metal foil; 82 . . . Metal foil
10 . . . High frequency power source; 11 . . . Matching unit; 12 . . . Chamber;
13 . . . Vacuum pumping system; 14 . . . Electrode; 15 . . . Electrode lifting mechanism;
16 . . . Rotating stage; 17 . . . Halogen heater; 18 . . . Inner tube; 19 . . . Outer tube;
21 . . . Radiation thermometer

1. A resin film comprising:
a polyimide film; and
a first polytetrafluoroethylene film that is directly laminated on the polyimide film, wherein
a peel strength when the first polytetrafluoroethylene film is peeled off is 0.5 N/mm or more.

2. The resin film according to claim 1, further comprising a second polytetrafluoroethylene film that is directly laminated on the polyimide film, wherein
the first polytetrafluoroethylene film, the polyimide film, and the second polytetrafluoroethylene film are arranged in this order in a thickness direction of the resin film, and
a peel strength when the second polytetrafluoroethylene film is peeled off is 0.5 N/mm or more.

3. The resin film according to claim 2, wherein the resin film has a relative permittivity of 3.0 or less at 28 GHz.

4. The resin film according to claim 2, wherein the resin film has a dielectric loss tangent of 0.004 or less at 28 GHz.

5. The resin film according to claim 2, wherein a total thickness of the first polytetrafluoroethylene film and the second polytetrafluoroethylene film is 60% or more and 90% or less in 100% of a total thickness of the first polytetrafluoroethylene film, the polyimide film, and the second polytetrafluoroethylene film.

6. The resin film according to claim 1, wherein the polyimide film contains a polyimide containing a polyimide benzoxazole component.

7. The resin film according to claim 1, wherein the resin film is used to produce at least one of a metal-clad laminate or a printed wiring board.

8. A metal-clad laminate comprising:
the resin film according to claim 1; and
a metal foil that is provided with the first polytetrafluoroethylene film of the resin film.

9. A printed wiring board that is produced using the resin film according to claim 1.

10. A method for producing the resin film according to claim 1, the method comprising:
a step of performing a plasma treatment on a surface of the first polytetrafluoroethylene film at an oxygen concentration of less than 0.5% by volume; and
a step of performing thermocompression bonding on the plasma-treated first polytetrafluoroethylene film and the polyimide film in a state where the plasma-treated surface of the first polytetrafluoroethylene film faces the polyimide film, wherein
a temperature of the surface of the first polytetrafluoroethylene film is 180° C. or more in the step of performing the plasma treatment.

11. The resin film according to claim 1, wherein the peel strength when the first polytetrafluoroethylene film is peeled off is 0.7 N/mm or more.

12. The resin film according to claim 1, wherein the peel strength when the first polytetrafluoroethylene film is peeled off is 0.9 N/mm or more.

13. The resin film according to claim 2, wherein the peel strength when the second polytetrafluoroethylene film is peeled off is 0.7 N/mm or more.

14. The resin film according to claim 2, wherein the peel strength when the second polytetrafluoroethylene film is peeled off is 0.9 N/mm or more.

15. The resin film according to claim 1, wherein thickness of the first polytetrafluoroethylene film is 5 μm or more and 100 μm or less.

16. The resin film according to claim 1, wherein thickness of the first polytetrafluoroethylene film is 15 μm or more.

17. The resin film according to claim 1, wherein thickness of the polyimide film is 1 μm or more and 60 μm or less.

18. The resin film according to claim 1, wherein thickness of the polyimide film is 5 μm or more.

19. The metal-clad laminate according to claim 8, wherein the metal foil includes at least one of copper or a copper alloy.
